(19) United States
(12) Patent Application Publication
(10) Pub. No.: US 2024/0063302 A1
(43) Pub. Date: Feb. 22, 2024

(54) SEMICONDUCTOR STRUCTURES

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/449,396

(22) Filed: Aug. 14, 2023

(30) Foreign Application Priority Data
Aug. 19, 2022 (CN) 202211003355.7

(51) Int. Cl. H01L 29/778; H01L 29/20

(52) U.S. Cl. CPC H01L 29/7786; H01L 29/2003

(57) ABSTRACT

A semiconductor structure is provided, and comprises: a substrate, an insulation layer and a protruding structure. The insulation layer is located on the substrate, and the protruding structure protrudes from the insulation layer, where the protruding structure further includes a first heterojunction structure, a second heterojunction structure, . . . , and an n-th heterojunction structure that are sequentially stacked in a direction away from the substrate, and n is greater than or equal to 2, wherein the first heterojunction structure includes a first channel layer and a first barrier layer, the second heterojunction structure includes a second channel layer and a second barrier layer, . . . , and the n-th heterojunction structure includes an n-th channel layer and an n-th barrier layer, and component proportions of at least two of the first barrier layer, the second barrier layer, . . . , or the n-th barrier layer are different.

### CROSS REFERENCE TO RELATED APPLICATIONS

This application claims priority to Chinese Patent Application No. 2022110033557, and filed on Aug. 19, 2022, the entire content of which is incorporated herein by reference.

### TECHNICAL FIELD

The present disclosure relates to the field of semiconductor technology, in particular to semiconductor structures.

### BACKGROUND

Wide-bandgap semiconductor material, group III nitrides, as a typical representative of the third-generation semiconductor materials, has excellent properties of wide band gap, high voltage resistance, high temperature resistance, high electron saturation velocity, high drift velocity and easy formation of a high-quality heterojunction structure, which is suitable for manufacturing a high-temperature, high-frequency and high-power electronic device.

In order to further promote the application of heterojunction devices in fields with higher currents and higher frequencies, it is necessary to research multi-channel and multi-heterojunction materials and devices. Compared with the single channel heterojunction structure, the double channel heterojunction structure can have a higher total concentration of 2DEG, which substantially increases the device saturation current. However, the increase in the total barrier layer thickness of the dual channel heterojunction material results in an increase in the distance between the device gate and the underlying channel, which reduces the gate control ability and the peak transconductance of the device. The linear operating characteristics need to be further improved.

In fields such as communication, the linearity of a semiconductor device is an important parameter. However, due to factors such as the decrease in the electron saturation speed and the increase in the device series resistance, the transconductance of the ordinary HEMT (High electron mobility transistor) device will increase with the increase of the gate-source bias voltage, and then decrease after reaching a certain peak value. The decrease of the transconductance can affect the linearity of the device.

### SUMMARY

The present disclosure provides a semiconductor structure, comprising:
a substrate;
an insulation layer on the substrate;
a protruding structure protruding from the insulation layer, wherein the protruding structure comprises a source region, a drain region and a channel region between the source region and the drain region, and the protruding structure further includes a first heterojunction structure, a second heterojunction structure, . . . , and an n-th heterojunction structure that are sequentially stacked in a direction away from the substrate, and n is greater than or equal to 2, wherein the first heterojunction structure includes a first channel layer and a first barrier layer, the second heterojunction structure includes a second channel layer and a second barrier layer, . . . , and the n-th heterojunction structure includes an n-th channel layer and an n-th barrier layer, and component proportions of at least two of the first barrier layer, the second barrier layer, . . . , or the n-th barrier layer are different; and
a source electrode on the source region, a drain electrode on the drain region and a gate structure on the channel region.

In some embodiments, materials of the first barrier layer, the second barrier layer, . . . , and the n-th barrier layer include AlGaN.

In some embodiments, proportions of Al in the first barrier layer, the second barrier layer, . . . , and the n-th barrier layer gradually decrease layer by layer from bottom to top.

In some embodiments, proportions of Al in the first barrier layer, the second barrier layer, . . . , and the n-th barrier layer first increase and then decrease layer by layer from bottom to top.

In some embodiments, the number of barrier layers above a barrier layer with a highest proportion of Al is greater than or equal to the number of barrier layers below the barrier layer with the highest proportion of Al.

In some embodiments, a proportion of Al of at least one of the first barrier layer, the second barrier layer, . . . , or the n-th barrier layer remains unchanged, gradually decreases or gradually increases.

In some embodiments, there are a plurality of the protruding structures, the source electrodes are on multiple source regions, the drain electrodes are on multiple drain regions, and the gate structure are on multiple channel regions.

In some embodiments, at least two of the plurality of the protruding structures have different heights or widths.

In some embodiments, from bottom to top, thicknesses of the first barrier layer, the second barrier layer, . . . , and the n-th barrier layer gradually decrease layer by layer from bottom to top.

In some embodiments, a width of the first heterojunction structure is greater than a width of any one of the second heterojunction structure, . . . , and the n-th heterojunction structure; or a width of the n-th heterojunction structure is smaller than a width of any one of the first heterojunction structure, the second heterojunction structure, . . . , and the (n−1)-th heterojunction structure.

In some embodiments, widths of the first heterojunction structure, the second heterojunction structure, . . . , and the n-th heterojunction structure gradually decrease.

### BRIEF DESCRIPTION OF DRAWINGS

FIG. 1 is a cross-sectional structural diagram of a semiconductor structure according to a first embodiment of the present disclosure.

FIG. 2 is a top view of the semiconductor structure in FIG. 1.

FIG. 3 is a top view of the semiconductor structure in FIG. 2 after a source electrode, a drain electrode and a gate electrode are removed.

FIG. 4 is a cross-sectional structural diagram of a semiconductor structure according to a second embodiment of the present disclosure.

FIG. 5 is a cross-sectional structural diagram of a semiconductor structure according to a third embodiment of the present disclosure.

FIG. 6 is a cross-sectional structural diagram of a semiconductor structure according to a fourth embodiment of the present disclosure.

FIG. 7 is a cross-sectional structural diagram of a semiconductor structure according to a fifth embodiment of the present disclosure.

For the convenience of understanding the present disclosure, all reference numerals appearing in the present disclosure are listed below.

| | |
|---|---|
| substrate 10 | insulation layer 11 |
| protruding structure 12 | source region 12a |
| drain region 12b | channel region 12c |
| first heterojunction structure 121 | first channel layer 121a |
| first barrier layer 121b | second heterojunction |
| second channel layer 122a | structure 122 |
| third heterojunction structure 123 | second barrier layer 122b |
| third barrier layer 123b | third channel layer 123a |
| drain electrode 14 | source electrode 13 |
| gate electrode 15a | gate structure 15 |
| semiconductor structure 1, 2, 3, 4, 5 | gate insulation layer 15b |

### DETAILED DESCRIPTION

In order to make the above-mentioned objects, features and advantages of the present disclosure more obvious and understandable, embodiments of the present disclosure will be described in detail below with reference to the accompanying drawings.

The present disclosure provides a semiconductor structure to improve the linear operating characteristics of HEMT devices.

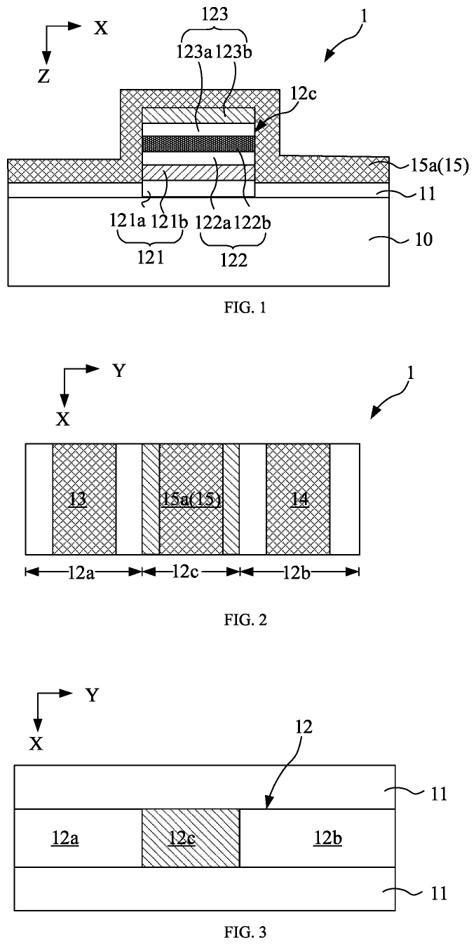

FIG. 1 is a cross-sectional structural diagram of a semiconductor structure according to a first embodiment of the present disclosure, FIG. 2 is a top view of the semiconductor structure in FIG. 1, and FIG. 3 is a top view of the semiconductor structure in FIG. 2 after a source electrode, a drain electrode and a gate electrode are removed.

As shown in FIGS. 1 to 3, a semiconductor structure 1 includes:
a substrate 10;
an insulation layer 11 on the substrate 10;
a protruding structure 12 protruding from the insulation layer 11, wherein the protruding structure 12 comprises a source region 12a, a drain region 12b and a channel region 12c between the source region 12a and the drain region 12b, and the protruding structure 12 further includes a first heterojunction structure 121, a second heterojunction structure 122 and a third heterojunction structure 123 that are sequentially stacked in a direction away from the substrate 10, wherein the first heterojunction structure 121 includes a first channel layer 121a and a first barrier layer 121b, the second heterojunction structure 122 includes a second channel layer 122a and a second barrier layer 122b and the third heterojunction structure 123 includes a third channel layer 123a and a third barrier layer 123b, and component proportions of the first barrier layer 121b, the second barrier layer 122b and the third barrier layer 123b are different; and
a source electrode 13 on the source region 12a, a drain electrode 14 on the drain region 12b, and a gate structure 15 on the channel region 12c.

A material of the substrate 10 may include sapphire, silicon carbide, silicon, or diamond.

A material of the insulation layer 11 can include silicon dioxide.

The protruding structure 12 is connected to the substrate 10. In this embodiment, the semiconductor structure 1 includes one protruding structure 12.

As shown in FIG. 1, taking the first heterojunction structure 121 as an example, the first heterojunction structure 121 includes a first channel layer 121a close to the substrate 10 and a first barrier layer 121b far from the substrate 10. An interface between the first channel layer 121a and the first barrier layer 121b can form a two-dimensional electron gas.

Materials of the first channel layer 121a and the first barrier layer 121b can both include GaN-based materials, and a band gap of the first barrier layer 121b is greater than a band gap of the first channel layer 121a. Material of the first barrier layer 121b can include AlGaN, and material of the first channel layer 121a can include GaN.

In this embodiment, the gate structure 15 includes a gate electrode 15a. Materials of the gate electrode 15a, the source electrode 13 and the drain electrode 14 may include metals, such as Ti/Al/Ni/Au, Ni/Au, etc. Schottky contact can be formed between the gate electrode 15a and the protruding structure 12, and ohmic contacts can be formed between the source electrode 13 and the source region 12a, and between the drain electrode 14 and the drain region 12b.

For factor a), in this embodiment, in the direction away from the substrate 10, the component proportions of the first channel layer 121a, the second channel layer 122a, and the third channel layer 123a are fixed, and the proportions of Al in the first barrier layer 121b, the second barrier layer 122b and the third barrier layer 123b gradually decrease. A proportion of Al in the third barrier layer 123b is smaller than a proportion of Al in the second barrier layer 122b, and a two-dimensional electron gas concentration of the third heterojunction structure 123 is smaller than a two-dimensional electron gas concentration of the second heterojunction structure 122. The proportion of Al in the second barrier layer 122b is smaller than a proportion of Al in the first barrier layer 121b, and the two-dimensional electron gas concentration of the second heterojunction structure 122 is smaller than a two-dimensional electron gas concentration of the first heterojunction structure 121. The higher the concentration of two-dimensional electron gas in the heterojunction structure, the poorer the control ability of the gate electrode 15a on the heterojunction structure, and the more the peak transconductance shifts towards a negative direction. On the contrary, the more the peak transconductance shifts towards a positive direction.

For factor b), in addition, the large concentration of the two-dimensional electron gas in heterojunction structure can significantly increase the saturation current of the device. For a power-application device, the improvement of the saturation current is crucial. The saturation current of a device corresponding to the first heterojunction structure 121 is greater than the saturation current of a device corresponding to the second heterojunction structure 122, and the saturation current of a device corresponding to the second heterojunction structure 122 is greater than the saturation current of a device corresponding to the third heterojunction structure 123. The higher the saturation current of a device corresponding to a heterojunction structure, the greater the peak transconductance value, on the contrary, the smaller the peak transconductance value.

For factor c), thirdly, the third heterojunction structure 123 is close to the gate electrode 15a, and the first heterojunction structure 121 is far from the gate electrode 15a. The closer a heterojunction structure is to the gate electrode 15a, the stronger the control ability of the gate electrode 15a on the heterojunction structure, the more the peak transconductance shifts towards the positive direction, and the larger the peak transconductance. On the contrary, the more the peak transconductance shifts towards the negative direction, and the smaller the peak transconductance.

The semiconductor structure 1 of this embodiment can be regarded as a parallel connection of several devices with different transconductance distributions. Combining the above three factors a), b) and c), the Al proportion of each barrier layer is different to realize a mutual compensation of transconductances. Through the structure of the parallel connection, mutual compensation of different transconductances of the device is achieved, thereby achieving a relative stable transconductance value within a large gate-source bias voltage range, which makes the semiconductor structure 1 have good linearity.

In addition, the semiconductor structure 1 of this embodiment can effectively reduce the sheet resistance and contact resistance of the epitaxial structure, which improves the frequency characteristic of the device. Thirdly, the preparation and process adjustment of the semiconductor structure 1 introduce small additional effects and have higher feasibility and repeatability, maintaining high linearity and achieving high breakdown voltage and high output current.

In this embodiment, for the first barrier layer 121b, the second barrier layer 122b, and the third barrier layer 123b, the sizes, shapes and materials are the same, and proportions of Al component are different. The parameters of the first channel layer 121a, the second channel layer 122a, and the third channel layer 123a are the same. For example, the sizes, shapes and materials of the first channel layer 121a, the second channel layer 122a, and the third channel layer 123a are the same.

In other embodiments, in the semiconductor structure 1, a proportion of Al in the first barrier layer 121b can be greater than a proportion of Al in either the second barrier layer 122b or the third barrier layer 123b. Or, a proportion of Al in the third barrier layer 123b is smaller than a proportion of Al in either the first barrier layer 121b or the second barrier layer 122b.

In other embodiments, the protruding structure 12 may include a first heterojunction structure 121, a second heterojunction structure 122, . . . , and an n-th heterojunction structure that are sequentially stacked in a direction away from the substrate 10, n≥2, where the first heterojunction structure 121 includes a first channel layer 121a and a first barrier layer 121b, the second heterojunction structure 122 includes a second channel layer 122a and a second barrier layer 122b, . . . , the n-th heterojunction structure includes an n-th channel layer and an n-th barrier layer, where component proportions of the first channel layer 121a, the second channel layer 122a, . . . , and the n-th channel layer are fixed, and a proportion of Al in the first barrier layer 121b is greater than a proportion of Al in any one of the second barrier layer 122b, . . . , and the n-th barrier layer; or a proportion of Al in the n-th barrier layer is smaller than proportion of Al in any one of the first barrier layer 121b, the second barrier layer 122b, . . . , and the (n−1)-th barrier layer, where n is 2, 3, 4 or more. For example, the proportions of Al in the first barrier layer 121b, the second barrier layer 122b, . . . , and the n-th barrier layer can gradually decrease, or increase first and then decrease, or a proportion of Al in at least one barrier layer remains unchanged, gradually decreases, or gradually increases.

For the embodiments where the proportions of Al in the first barrier layer 121b, the second barrier layer 122b, . . . , and the n-th barrier layer increase first and then decrease, the number of barrier layers above the barrier layer with the highest Al proportion can be greater than or equal to the number of barrier layers below the barrier layer with the highest Al proportion.

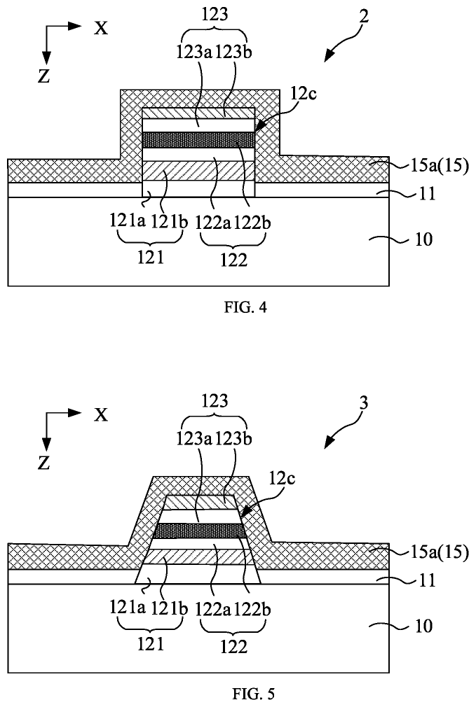

FIG. 4 is a cross-sectional structural diagram of a semiconductor structure according to a second embodiment of the present disclosure.

As shown in FIG. 4, a semiconductor structure in the second example is roughly the same as the semiconductor structure in the first embodiment, except that in the semiconductor structure 2, the thicknesses of the first barrier layer 121b, the second barrier layer 122b, and the third barrier layer 123b gradually decrease.

For factor d), in this embodiment, the thicknesses of the first channel layer 121a, the second channel layer 122a, and the third channel layer 123a are the same, and the thicknesses of the first barrier layer 121b, the second barrier layer 122b, and the third barrier layer 123b gradually decrease. The greater a thickness of a barrier layer, the greater a saturation current in a heterojunction structure, and the greater the peak value of transconductance. For a power-application device, the improvement of the saturation current is crucial. By adjusting thicknesses of different barrier layers, the saturation current of each heterojunction structure is adjusted, and then the transconductance peak of each heterojunction structure tends to be uniform.

Combining the two above factors c) and d), in this embodiment, by the different thicknesses of different barrier layers, mutual compensation of different transconductances of the device is achieved, thereby achieving a relative stable transconductance value within a large gate-source bias voltage range, which makes the semiconductor structure 2 have good linearity.

In this embodiment, the first barrier layer 121b, the second barrier layer 122b, and the third barrier layer 123b have the same parameters except for the different thicknesses. The parameters of the first channel layer 121a, the second channel layer 122a, and the third channel layer 123a are the same.

In other embodiments, in the semiconductor structure 1, the thickness of the first barrier layer 121b may be greater than the thickness of either the second barrier layer 122b or the third barrier layer 123b. Or, the thickness of the third barrier layer 123b is less than the thickness of either the first barrier layer 121b or the second barrier layer 122b.

In other embodiments, the protruding structure 12 may include a first heterojunction structure 121, a second heterojunction structure 122, . . . , and an n-th heterojunction structure that are sequentially stacked in a direction away from the substrate 10, n≥2, where the first heterojunction structure 121 includes a first channel layer 121a and a first barrier layer 121b, the second heterojunction structure 122 includes a second channel layer 122a and a second barrier layer 122b, . . . , the n-th heterojunction structure includes an n-th channel layer and an n-th barrier layer, where thicknesses of the first channel layer 121a, the second channel layer 122a, . . . , and the n-th channel layer are the same, and the thickness of the first barrier layer 121b is greater than the thickness of any one of the second barrier layer 122b, . . . , and the n-th barrier layer; or the thickness of the n-th barrier layer is smaller than the thickness of any one of the first barrier layer 121b, the second barrier layer 122b, . . . , and the (n−1)-th barrier layer, where n is 2, 3, 4 or more. For example, the thicknesses of the first barrier layer 121b, the second barrier layer 122b, . . . , and the n-th barrier layer can gradually decrease.

FIG. 5 is a cross-sectional structural diagram of a semiconductor structure according to a third embodiment of the present disclosure.

As shown in FIG. 5, a semiconductor structure in the third embodiment is roughly the same as the semiconductor structure in the first embodiment, except that in the semiconductor structure 3, widths of the first heterojunction structure 121, the second heterojunction structure 122, . . . , and the n-th heterojunction structure gradually decrease.

For factor e), in this embodiment, the widths of the first channel layer 121a, the second channel layer 122a, and the third channel layer 123a gradually decrease, and the widths of the first barrier layer 121b, the second barrier layer 122b, and the third barrier layer 123b gradually decrease. The larger a width of a barrier layer in a heterojunction structure, the poorer the control ability of the gate electrode 15a on the heterojunction structure, and the more the peak transconductance shifts towards a negative direction. On the contrary, the more the peak transconductance shifts towards a positive direction. On the other hand, the larger a width of a barrier layer in a heterojunction structure, the greater a saturation current in the heterojunction structure, and correspondingly the greater the peak value of transconductance. For a power-application device, the improvement of the saturation current is crucial. By adjusting widths of different barrier layers, the saturation current of each heterojunction structure is adjusted, and then the transconductance peak of each heterojunction structure tends to be uniform.

Combining the two above factors c) and e), in this embodiment, by the different widths of barrier layers of different heterojunction structures, mutual compensation of different transconductances of the device is achieved, thereby achieving a relative stable transconductance value within a large gate-source bias voltage range, which makes the semiconductor structure 3 have good linearity.

In this embodiment, the first heterojunction structure 121, the second heterojunction structure 122, and the third heterojunction structure 123 have the same parameters except for different widths.

In other embodiments, the width of the first heterojunction structure 121 may be greater than the width of any one of the second heterojunction structure 122, . . . , and the n-th heterojunction structure, or the width of the n-th heterojunction structure may be smaller than the width of any one of the first heterojunction structure 121, the second heterojunction structure 122, . . . , and the (n−1)-th heterojunction structure.

In other embodiments, the protruding structure 12 may include a first heterojunction structure 121, a second heterojunction structure 122, . . . , and an n-th heterojunction structure that are sequentially stacked in a direction away from the substrate 10, n≥2, where the first heterojunction structure 121 includes a first channel layer 121a and a first barrier layer 121b, the second heterojunction structure 122 includes a second channel layer 122a and a second barrier layer 122b, . . . , the n-th heterojunction structure includes an n-th channel layer and an n-th barrier layer, where the width of the first heterojunction structure 121 is greater than the width of any one of the second heterojunction structure 122, . . . , and the n-th heterojunction structure, or the width of the n-th heterojunction structure is smaller than the width of any one of the first heterojunction structure 121, the second heterojunction structure 122, . . . , and the (n−1)-th heterojunction structure, where n is 2, 3, 4 or more. For example, the widths of the first heterojunction structure 121, the second heterojunction structure 122, . . . , and the n-th heterojunction structure can gradually decrease.

In other embodiments, the widths of the first heterojunction structure 121, the second heterojunction structure 122, and the third heterojunction structure 123 can also gradually decrease in a step wise.

In other embodiments, the solutions of the first to third embodiments mentioned above can be used in combination with all or any two of them.

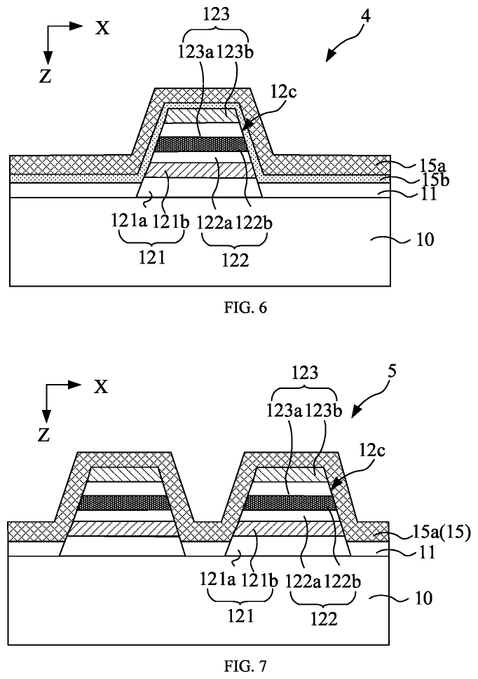

FIG. 6 is a cross-sectional structural diagram of a semiconductor structure according to a fourth embodiment of the present disclosure.

As shown in FIG. 6, a semiconductor structure in the fourth embodiment is roughly the same as the semiconductor structures in the first to third embodiments, except that in the semiconductor structure 4, the gate structure 15 includes a gate insulation layer 15b and a gate electrode 15a.

In other words, the semiconductor structure 4 is a MIS-HEMT transistor.

A material of the gate insulation layer 15b can include silicon dioxide, or hafnium oxide, etc.

FIG. 7 is a cross-sectional structural diagram of a semiconductor structure according to a fifth embodiment of the present disclosure.

As shown in FIG. 7, a semiconductor structure of the fifth embodiment is roughly the same as the semiconductor structures of the first to fourth embodiments, except that in the semiconductor structure 5, there are a plurality of the protruding structures 12, the source electrode 13 covers multiple source regions 12a, the drain electrode 14 covers multiple drain regions 12b, and the gate structure 15 covers multiple channel regions 12c.

Compared to one channel region 12c, multiple channel regions 12c can form multiple parallel channels between the source electrode 13 and the drain electrode 14, which can reduce the conduction resistance of the semiconductor structure 5.

In some embodiment, multiple protruding structures 12 are connected between the source electrode 13 and the drain electrode 14, which increases a breakdown voltage and improves a dynamic characteristic. Multiple protruding structures 12 increase the gate control area, which enhances gate control capability, increases carrier density, maintains stable semiconductor mobility, reduces surface resistance, and greatly improves the frequency characteristic of the semiconductor structure 5.

In multiple protruding structures 12, at least two protruding structures 12 may have different heights or widths.

In this embodiment, the semiconductor structure 5 can be regarded as a parallel connection of several devices with different transconductance distributions. By the structure of the parallel connection, at least two of the protruding structures 12 have different heights or widths, which achieves mutual compensation for different transconductances of the device. For the multiple protruding structures 12, the wider the protruding structure 12, the flatter and smaller the transconductance, the narrower the protruding structure 12, the narrower and higher the transconductance, which achieves a relative stable transconductance value within a large gate-source bias voltage range.

Compared with the prior art, the present disclosure has the following beneficial effects:

In some embodiments, compared to planar HEMT devices, a semiconductor structure utilizes a gate electrode to control a channel on three surfaces to improve channel control capability of the gate electrode. In addition, the protruding structure includes n heterojunction structures stacked in a thickness direction. By varying a component proportion, a thickness, and/or a width of a barrier layer of each heterojunction structure, a peak transconductance corresponding to each heterojunction structure can be changed, and a threshold voltage of each heterojunction structure can be changed. By stacking multiple heterojunction structures, a linear operating characteristic of a device can be improved.

In some embodiments, through stacked multiple layers of heterojunction structures, the semiconductor structure provided in the present disclosure effectively reduces a sheet resistance and a contact resistance of an epitaxial structure, and improves a frequency characteristic of a device. The component proportions of at least two barrier layers are different to achieve mutual compensation of transconductance, achieve a relatively stable transconductance within a large gate-source bias voltage range, and increase an electron saturation rate, which can make a device have good linearity. The device preparation and process adjustment through the present disclosure introduce small additional effects and have higher feasibility and repeatability. High linearity is maintained and high breakdown voltage and high output current are achieved.

In some embodiments, the lower the heterojunction structure, the weaker the control ability of the gate electrode on the heterojunction structure, the lower the peak transconductance value of the device, and the lower the linear operating characteristics. In the present disclosure, by decreasing the Al proportions in the multiple barrier layers from bottom to top, the high Al proportion in the lower barrier layer can have a higher 2DEG density, and the saturation current of the device is greatly increased. For devices in power applications, the increase in saturation current is critical. By adjusting the Al proportions in different barrier layers, the saturation current of each heterojunction structure is adjusted, and then the peak transconductance of each heterojunction structure tends to be uniform. The semiconductor structure in the present disclosure can be regarded as a parallel connection of several devices with different transconductance distributions. Through the structure of the parallel connection, mutual compensation of different transconductances of the device is achieved, thereby achieving a relative stable transconductance value within a large gate-source bias voltage range, which makes the device have good linearity.

In some embodiments, a proportion of Al in a barrier layer can adjust the peak and distribution of transconductance. In the present disclosure, proportions of Al in multiple barrier layers first increase and then decrease layer by layer from bottom to top, which ensures the control of the top gate electrode to the bottom channel, and adjusts the linearity of the device.

In some embodiment, multiple protruding structures are connected between a source electrode and a drain electrode, which increases a breakdown voltage and improves a dynamic characteristic. Multiple protruding structures increase the gate control area, which enhances gate control capability, increases carrier density, maintains stable semiconductor mobility, reduces surface resistance, and greatly improves the frequency characteristic of the device.

In some embodiments, at least two of the protruding structures have different heights or widths, and the semiconductor structure in the present disclosure can be regarded as a parallel connection of several devices with different transconductance distributions. By the structure of the parallel connection, at least two of the protruding structures have different heights or widths, which achieves mutual compensation for different transconductances of the device. For the multiple protruding structures, the wider the protruding structure, the flatter and smaller the transconductance, the narrower the protruding structure, the narrower and higher the transconductance, which achieves a relative stable transconductance value within a large gate-source bias voltage range.

Although the present disclosure is disclosed as above, the present disclosure is not limited thereto. Any person skilled in the art can make various changes and modifications without departing from the spirit and scope of the present disclosure, and therefore the scope of protection of the present disclosure shall be subject to the scope defined by the claims.

What is claimed is:

1. A semiconductor structure, comprising:
a substrate;
an insulation layer on the substrate;
a protruding structure protruding from the insulation layer, wherein the protruding structure comprises a source region, a drain region and a channel region between the source region and the drain region, and the protruding structure further includes a first heterojunction structure, a second heterojunction structure, . . . , and an n-th heterojunction structure that are sequentially stacked in a direction away from the substrate, and n is greater than or equal to 2, wherein the first heterojunction structure includes a first channel layer and a first barrier layer, the second heterojunction structure includes a second channel layer and a second barrier layer, . . . , and the n-th heterojunction structure includes an n-th channel layer and an n-th barrier layer, and component proportions of at least two of the first barrier layer, the second barrier layer, . . . , or the n-th barrier layer are different; and
a source electrode on the source region, a drain electrode on the drain region and a gate structure on the channel region.

2. The semiconductor structure according to claim 1, wherein materials of the first barrier layer, the second barrier layer, . . . , and the n-th barrier layer include AlGaN.

3. The semiconductor structure according to claim 2, wherein proportions of Al in the first barrier layer, the second barrier layer, . . . , and the n-th barrier layer gradually decrease layer by layer from bottom to top.

4. The semiconductor structure according to claim 2, wherein proportions of Al in the first barrier layer, the second barrier layer, . . . , and the n-th barrier layer first increase and then decrease layer by layer from bottom to top.

5. The semiconductor structure according to claim 4, wherein the number of barrier layers above a barrier layer with a highest proportion of Al is greater than or equal to the number of barrier layers below the barrier layer with the highest proportion of Al.

6. The semiconductor structure according to claim 2, wherein a proportion of Al of at least one of the first barrier layer, the second barrier layer, . . . , or the n-th barrier layer remains unchanged, gradually decreases or gradually increases.

7. The semiconductor structure according to claim 1, wherein there are a plurality of protruding structures, the source electrode is on multiple source regions, the drain electrode is on multiple drain regions, and the gate structure is on multiple channel regions.

8. The semiconductor structure according to claim 7, wherein at least two of the plurality of the protruding structures have different heights or widths.

9. The semiconductor structure according to claim 1, wherein thicknesses of the first barrier layer, the second barrier layer, . . . , and the n-th barrier layer gradually decrease layer by layer from bottom to top.

10. The semiconductor structure according to claim 1, wherein a width of the first heterojunction structure is greater than a width of any one of the second heterojunction structure, . . . , and the n-th heterojunction structure; or a width of the n-th heterojunction structure is smaller than a width of any one of the first heterojunction structure, the second heterojunction structure, . . . , and the (n−1)-th heterojunction structure.

11. The semiconductor structure according to claim 10, wherein widths of the first heterojunction structure, the second heterojunction structure, . . . , and the n-th heterojunction structure gradually decrease.
